(19) United States
(12) Patent Application Publication
(10) Pub. No.: US 2025/0098554 A1
(43) Pub. Date: Mar. 20, 2025

(54) SEMICONDUCTOR DEVICE INCLUDING SELECTOR

(71) Applicant: SK hynix Inc., Icheon-si (KR)

(72) Inventor: Tae Jung HA, Icheon-si (KR)

(21) Appl. No.: 18/594,987

(22) Filed: Mar. 4, 2024

(30) Foreign Application Priority Data
Sep. 19, 2023 (KR) 10-2023-0124766

(51) Int. Cl. H10N 70/00; H10B 63/00

(52) U.S. Cl. CPC H10N 70/043; H10B 63/80; H10N 70/021; H10N 70/826; H10N 70/841

(57) ABSTRACT

A semiconductor device includes: a selector pattern including an insulating material having dopants implanted to the insulating material along an implantation direction and having a first sidewall and a second sidewall facing the first sidewall, the selector pattern configured to exhibit different electrical conducting characteristics in response to an applied voltage with respect to a threshold voltage; and a first electrode layer and a second electrode layer respectively formed over the first sidewall and the second sidewall of the selector pattern, wherein the implantation direction of the dopants is different from a direction of a current flowing through the selector pattern between the first electrode layer and the second electrode layer when the selector pattern is turned on.

### CROSS-REFERENCE TO RELATED APPLICATION

This patent document claims priority under 35 U.S.C. § 119 to Korean Patent Application No. 10-2023-0124766 filed on Sep. 19, 2023, which is incorporated herein by reference in its entirety.

### TECHNICAL FIELD

This patent document relates to a semiconductor technology, and more particularly, to a semiconductor device including a selector.

### BACKGROUND

Recently, as electronic appliances trend toward miniaturization, low power consumption, high performance, multi-functionality, and so on, semiconductor devices capable of storing information in various electronic appliances such as a computer, a portable communication device, and so on have been demanded in the art, and research has been conducted for the semiconductor devices. Such semiconductor devices include semiconductor devices which can store data using a characteristic that they are switched between different resistant states according to an applied voltage or current, for example, an RRAM (resistive random access memory), a PRAM (phase change random access memory), an FRAM (ferroelectric random access memory), an MRAM (magnetic random access memory), an E-fuse, etc.

### SUMMARY

In an embodiment, a semiconductor device may include: a selector pattern including an insulating material having dopants implanted to the insulating material along an implantation direction and having a first sidewall and a second sidewall facing the first sidewall, the selector pattern configured to exhibit different electrical conducting characteristics in response to an applied voltage with respect to a threshold voltage; and a first electrode layer and a second electrode layer respectively formed over the first sidewall and the second sidewall of the selector pattern, wherein the implantation direction of the dopants is different from a direction of a current flowing through the selector pattern between the first electrode layer and the second electrode layer when the selector pattern is turned on.

In another embodiment, a semiconductor device may include: a first conductive line and a second conductive line that are spaced apart from each other in a vertical direction; a selector pattern interposed between the first conductive line and the second conductive line in the vertical direction and including a first sidewall and a second sidewall facing the first sidewall in a horizontal direction, the selector pattern configured to exhibit different electrical conducting characteristics in response to an applied voltage with respect to a threshold voltage; a first electrode layer and a second electrode layer respectively formed over the first sidewall and the second sidewall of the selector pattern; a first contact plug having an upper surface in contact with a lower surface of the first electrode layer, the first contact plug electrically connected to the first conductive line and disposed over the first conductive line; and a second contact plug disposed at one side of the second electrode layer in the horizontal direction and having a sidewall in contact with the second electrode layer, the second contact plug electrically connected to the second conductive line and disposed under the second conductive line.

In another embodiment, a semiconductor device may include: a first conductive line and a second conductive line that are spaced apart from each other in a vertical direction; a selector pattern interposed between the first conductive line and the second conductive line in the vertical direction and including a first sidewall and a second sidewall that face each other in a horizontal direction; a first electrode layer and a second electrode layer that are respectively formed over the first sidewall and the second sidewall of the selector pattern; a memory pattern having an upper surface in contact with a lower surface of the first electrode layer, the memory pattern electrically connected to the first conductive line and disposed over the first conductive line; and a contact plug disposed at one side of the second electrode layer in the horizontal direction and having a sidewall in contact with the second electrode layer, the contact plug electrically connected to the second conductive line and disposed under the second conductive line.

### BRIEF DESCRIPTION OF THE DRAWINGS

FIG. 1 is a cross-sectional view illustrating a semiconductor device according to an embodiment of the present disclosure.

FIGS. 2A to 9B are views illustrating a semiconductor device and a method for fabricating the semiconductor device according to another embodiment of the present disclosure.

FIG. 10 is a cross-sectional view illustrating a semiconductor device and a method for fabricating the semiconductor device according to another embodiment of the present disclosure.

FIG. 11 is a cross-sectional view illustrating a semiconductor device, and a method for fabricating the semiconductor device according to another embodiment of the present disclosure.

FIG. 12 is a cross-sectional view illustrating a semiconductor device, and a method for fabricating the semiconductor device according to another embodiment of the present disclosure.

FIG. 13 is a cross-sectional view illustrating a semiconductor device, and a method for fabricating the semiconductor device according to another embodiment of the present disclosure.

FIG. 14 is a cross-sectional view illustrating a semiconductor device according to another embodiment of the present disclosure.

### DETAILED DESCRIPTION

Hereinafter, various embodiments of the disclosure will be described in detail with reference to the accompanying drawings.

The drawings are not necessarily drawn to scale. In some instances, proportions of at least some structures in the drawings may have been exaggerated in order to clearly illustrate certain features of the described embodiments. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure might not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

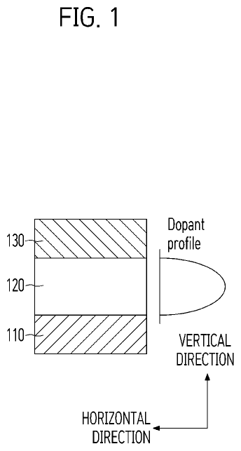

FIG. 1 is a cross-sectional view illustrating a semiconductor device according to an embodiment of the present disclosure.

Referring to FIG. 1, a semiconductor device of the present embodiment may include a first electrode layer 110, a second electrode layer 130, and a selector layer 120 interposed between the first electrode layer 110 and the second electrode layer 130. The first electrode layer 110, the selector layer 120, and the second electrode layer 130 may be stacked in a vertical direction substantially perpendicular to a surface of a wafer and/or a substrate (not shown).

Each of the first electrode layer 110 and the second electrode layer 130 may include a conductive material, for example, a metal such as platinum (Pt), tungsten (W), aluminum (Al), copper (Cu), tantalum (Ta), or titanium (Ti), a metal nitride such as titanium nitride (TiN) or tantalum nitride (TaN), carbon, or a combination thereof, and may have a single-layer structure or a multi-layer structure.

The selector layer 120 may have a threshold switching characteristic by exhibiting two different electrical conducting states: a first electrical conducting state in which a current is blocked or hardly flows in the selector layer 120 when the magnitude of the voltage supplied to the selector layer 120 is less than a predetermined threshold voltage, and a second electrical conducting state in which the current rapidly flows through the selector layer 120 at a voltage equal to or higher than the threshold voltage. Thus, the selector layer 120 may block a current or barely flow the current when a magnitude of a voltage supplied through the first and second electrode layers 110 and 130 is less than a predetermined threshold voltage, but may rapidly flow the current at a voltage equal to or greater than the threshold voltage. Accordingly, the selector layer 120 may be turned on at the threshold voltage or higher, and may be turned off at a voltage lower than the threshold voltage. The selector layer 120 may be electrically connected to the first electrode layer 110 or the second electrode layer 130, and may function to control access to a memory layer that stores data. Because the selector layer 120 exhibits different electrical conducting characteristics in response to an applied voltage with respect to a threshold voltage and thus can be controlled via the applied voltage to be selected in one of the two different electrical conducting states, the selector layer 120 functions as a selector for selecting whether the memory cell embodying the selector layer 120 is selected or not.

In an example, the selector layer 120 may include an insulating material doped with dopants. The insulating material may include an insulating material having a relatively wide band gap, for example, an insulating material having a band gap of 5.0 eV or more. In an example, the insulating material may include a silicon-containing insulating material such as silicon oxide, silicon nitride, or silicon oxynitride, an insulating metal oxide, an insulating metal nitride, or a combination thereof. Deep traps may exist within the insulating material with an energy level closer to an energy level of a valence band of the insulating material than to an energy level of a conduction band of the insulating material. The dopants may serve to create shallow traps that provide a path for movement of conductive carriers, such as electrons or holes, within the insulating material. The shallow traps may have an energy level that is closer to the energy level of the conduction band of the insulating material than to the energy level of the valence band of the insulating material. In an example, if the insulating material contains silicon, the dopants may include a metal with a different valence than silicon, such as gallium (Ga), boron (B), indium (In), phosphorus (P), arsenic (As), antimony (Sb), germanium (Ge), carbon (C), tungsten (W), or a combination thereof. Alternatively, if the insulating material contains a metal, the dopants may include another metal having a different valence than the metal, or silicon. In an example, the selector layer 120 may include silicon dioxide (SiO₂) doped with arsenic (As).

In an off-state in which no voltage is applied to the selector layer 120, the conductive carriers, such as electrons, may be trapped in the deep traps of the selector layer 120. When a voltage equal to or higher than the threshold voltage is applied to the selector layer 120 in the off-state through the first and second electrode layers 110 and 130, a current flows through the selector layer 120, which makes the selector layer 120 turn on to be in an on-state. When a voltage equal to or higher than the threshold voltage is applied to the selector layer 120, the conductive carriers trapped in the deep traps may jump to the shallow traps by thermal emission or tunneling, and the conductive carriers may move through the shallow traps, thereby forming a current flow connecting the first electrode layer 110 and the second electrode layer 130. The current flow may be formed in a substantially vertical direction. When a voltage applied to the selector layer 120 in the on-state decreases, the number of the conductive carriers moving from the deep traps to the shallow traps may decrease, and thus, the selector layer 120 may be turned off again.

The selector layer 120 may be formed by depositing an insulating material layer and performing an ion-implanting process of dopants into the insulating material layer. The direction along which the ions are implanted into the insulation material layer, which is referred to as the ion implantation direction, may be substantially parallel to the vertical direction. During the ion implantation process, the depth at which the dopants are implanted into the insulating material layer may vary depending on the ion implantation energy. For example, if the ion implantation energy is large, the dopants may be deeply injected into the insulating material layer, and if the ion implantation energy is low, the dopants may be thinly injected into the insulating material layer. When the ion implantation process is performed with a fixed ion implantation energy, the concentration of the dopants may vary depending on the depth of the insulating material layer and may be spatially graded along the implantation direction. For example, the concentration of the dopants in the selector layer 120 may exhibit a spatially increasing dopant concentration along the implantation direction at the top portion of the selector layer 120 and then a spatially decreasing dopant concentration after reaching a peak dopant concentration. In some implementations, this spatially varying dopant concentration along the implantation direction may generally show a Gaussian distribution. Referring to the dopant profile as shown on the right side of the selector layer 120, the dopant concentration may be highest at a certain depth, for example, the middle depth, of the selector layer 120, and the dopant concentration may dramatically decrease as further away from the middle depth of the selector layer 120. Thus, the dopant concentration decreases as the depth moves up and down from the certain depth of the selector layer 120 at which the dopant concentration is the highest.

As described above, since the current flows through the selector layer 120 and between the first electrode layer 110 and the second electrode layer 130, the current flow may occur in a direction substantially parallel to the vertical direction. For this reason, when the dopant concentration changes rapidly in the vertical direction, the switching characteristic of the selector layer 120 may deteriorate. For example, breakdown may occur in a portion of the selector layer 120 where the dopant concentration is low, causing a problem in which the selector layer 120 cannot be turned on/off normally.

Hereinafter, a semiconductor device including a selector layer with a substantially uniform dopant concentration in a direction in which a current flows, and a method for fabricating the same.

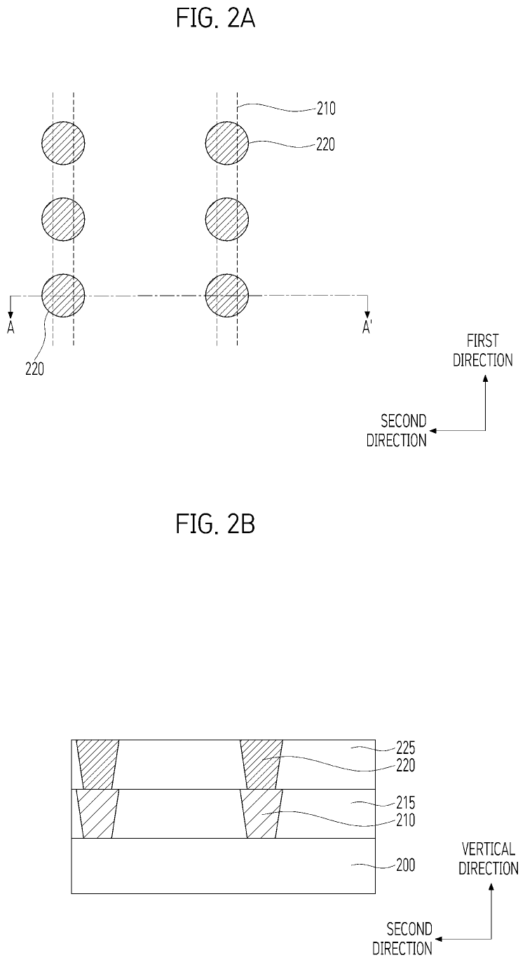

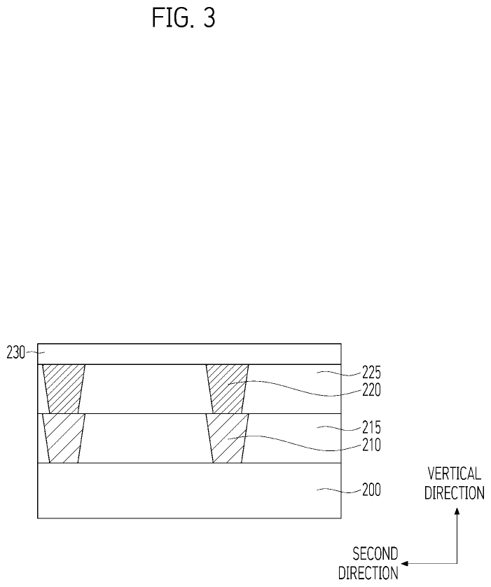

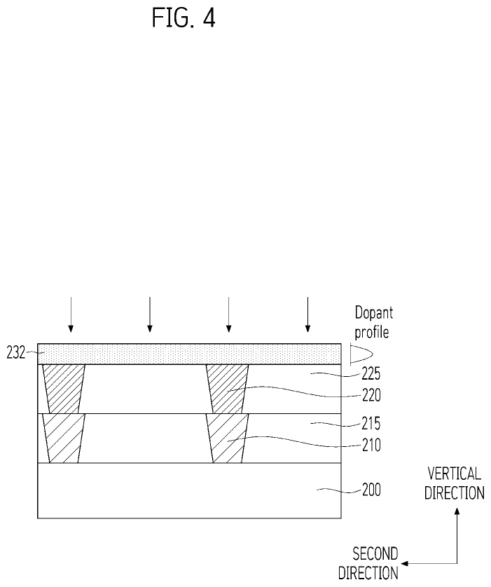

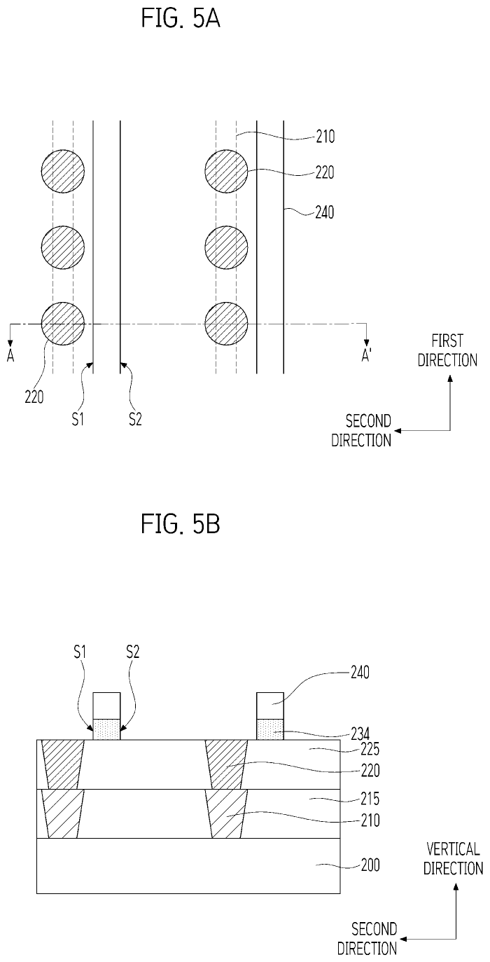

FIGS. 2A to 9B are views illustrating a semiconductor device and a method for fabricating the same based on another embodiment of the present disclosure. FIGS. 2A, 5A, 6A, 7A, 8A, and 9A are plan views of the semiconductor device from above, and FIGS. 2B, 5B, 6B, 7B, 8B, and 9B are cross-sectional views taken along lines A-A′ of FIGS. 5A, 6A, 7A, 8A, and 9A, respectively. FIGS. 3 and 4 are cross-sectional views illustrating processes between the process of FIG. 2B and the process of FIG. 5B.

First, the fabricating method will be described.

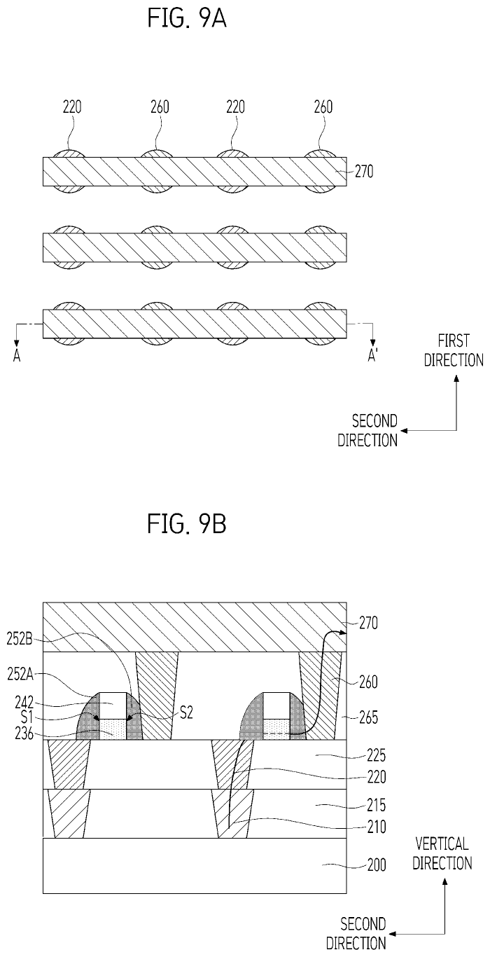

Referring to FIGS. 2A and 2B, a substrate 200 may be provided. The substrate 200 may include a semiconductor material such as silicon. Additionally, the substrate 200 may include required substructures. For example, the substrate 200 may include a driving circuit that is electrically connected to a first conductive line 210 and/or a second conductive line 270 (see FIGS. 9A and 9B) and drives the first conductive line 210 and/or the second conductive line 270. The first conductive line 210 and the second conductive line 270 will be described later in this patent document.

The first conductive line 210 and a first interlayer insulating layer 215 may be formed over the substrate 200. The first conductive line 210 may extend in a first direction. A plurality of first conductive lines 210 may be arranged to be spaced apart from each other in a second direction. For reference, the first direction and the second direction may correspond to horizontal directions substantially parallel to the upper surface of the substrate 200. A direction substantially perpendicular to the upper surface of the substrate 200 will hereinafter be referred to as a vertical direction. The first conductive line 210 may include a conductive material, for example, a metal such as platinum (Pt), tungsten (W), aluminum (Al), copper (Cu), tantalum (Ta), or titanium (Ti), a metal nitride such as titanium nitride (TiN) or tantalum nitride (TaN), or a combination thereof, and may have a single-layer structure or a multi-layer structure. The first interlayer insulating layer 215 may be formed to fill the space between the plurality of first conductive lines 210. The first interlayer insulating layer 215 may include silicon oxide, silicon nitride, silicon oxynitride, or a combination thereof, and may have a single-layer structure or a multi-layer structure. In the present embodiment, the first conductive line 210 and the first interlayer insulating layer 215 may be formed by depositing an insulating material for forming the first interlayer insulating layer 215 over the substrate 200, selectively etching the insulating material to form a line-shaped trench that provides a space in which the first conductive line 210 is to be formed, and filling the trench with a conductive material. Accordingly, the first conductive line 210 may have a shape whose width decreases from top to bottom. However, in another embodiment, the first conductive line 210 and the first interlayer insulating layer 215 may be formed by depositing a conductive material for forming the first conductive line 210 over the substrate 200, selectively etching the conductive material to form the first conductive line 210, and filling the space between the first conductive lines 210 with an insulating material to form the first interlayer insulating layer 215. In this case, the first conductive line 210 may have a width that increases from top to bottom.

Subsequently, a first contact plug 220 and a second interlayer insulating layer 225 may be formed over the first conductive line 210 and the first interlayer insulating layer 215. The first contact plug 220 may have a pillar shape, and a plurality of first contact plugs 220 may be arranged in a matrix form along the first and second directions. For convenience of description, the plurality of first contact plugs 220 arranged in the first direction will be referred to as a column of first contact plugs 220, and the plurality of first contact plugs 220 arranged in the second direction will be referred to as a row of first contact plugs 220. The column of first contact plugs 220 may overlap and connect to the first conductive line 210 corresponding thereto. The first contact plug 220 may include at least one of various conductive materials, and may have a single-layer structure or a multi-layer structure. The second interlayer insulating layer 225 may be formed to fill the space between the plurality of first contact plugs 220. In the present embodiment, the first contact plug 220 and the second interlayer insulating layer 225 may be formed by depositing an insulating material for forming the second interlayer insulating layer 225 over the first conductive line 210 and the first interlayer insulating layer 215, selectively etching the insulating material to form a hole that provides a space in which the first contact plug 220 is to be formed, and filling the hole with a conductive material. Accordingly, the first contact plug 220 may have a shape whose width decreases from top to bottom. However, in another embodiment, the first contact plug 220 and the second interlayer insulating layer 225 may be formed by depositing a conductive material over the first conductive line 210 and the first interlayer insulating layer 215, selectively etching the conductive material to form the first contact plug 220 having a pillar shape, and filling the space between the first contact plugs 220 with an insulating material to form the second interlayer insulating layer 225. In this case, unlike what is shown, the first contact plug 220 may have a width that increases from top to bottom.

Referring to FIG. 3, an insulating material layer 230 may be formed over the first contact plug 220 and the second interlayer insulating layer 225.

The insulating material layer 230 may have a plate shape that covers the first contact plug 220 and the second interlayer insulating layer 225. The insulating material layer 230 may be formed by depositing an insulating material. As discussed below, a selector layer is to be formed by doping the insulating material layer 230 with dopants. Thus, the insulating material layer 230 is disposed to form a selector. In an example, the insulating material layer 230 may include a silicon-containing insulating material such as silicon oxide, silicon nitride, or silicon oxynitride, an insulating metal oxide, an insulating metal nitride, or a combination thereof. In particular, for example, the insulating material layer 230 may include silicon dioxide.

Referring to FIG. 4, a selector layer 232 may be formed by doping the insulating material layer 230 with dopants.

The dopants may create shallow traps within the insulating material layer 230. The shallow traps may provide a path for movement of conductive carriers, such as electrons or holes. The dopants may include an element having a different valence from the constituent elements of the insulating material layer 230. For example, the dopants may include gallium (Ga), boron (B), indium (In), phosphorus (P), arsenic (As), antimony (Sb), germanium (Ge), carbon (C), tungsten (W), or a combination thereof. When the insulating material layer 230 includes silicon dioxide, the dopants may include arsenic.

Doping of the dopants may be performed by ion implantation, and may be performed in a vertical direction toward the upper surface of the insulating material layer 230, that is, from top to bottom (see arrow as shown in FIG. 4). In this case, the concentration of the dopants within the selector layer 232 may be maximum at a certain depth, e.g., at a depth about half the thickness of the selector layer 232, and may decrease in the vertical direction as the depth move away from the certain depth, as shown by the dopant profile on the right side of the selector layer 232. Thus, in the vertical direction, the dopant concentration of the selector layer 232 may not be uniform, and may vary. On the other hand, in a horizontal direction substantially parallel to the upper surface of the substrate 200, for example, in the second direction, the dopant concentration may be substantially uniform. Referring to FIGS. 5A and 5B, an initial hard mask pattern 240 may be formed over the selector layer 232, and then, the selector layer 232 may be etched using the initial hard mask pattern 240 as an etch barrier to form an initial selector pattern 234.

The initial hard mask pattern 240 may have a single-layer structure or a multi-layer structure including at least one of various insulating materials. The initial hard mask pattern 240 may have a line shape extending in the first direction, and may be disposed at one side of a corresponding column of first contact plugs 220 in the second direction to be spaced apart from the corresponding column of first contact plugs 220 by a predetermined distance. In an example, as shown, in the second direction, a left initial hard mask pattern 240 may be disposed at a right side of a left column of first contact plugs 220 to be spaced apart from the left column of first contact plugs 220, and a right initial hard mask pattern 240 may be disposed at a right side of a right column of first contact plugs 220 to be spaced apart from the right column of first contact plugs 220. Furthermore, in the second direction, the initial hard mask pattern 240 may be disposed between the corresponding column of first contact plugs 220 and another column of first contact plugs 220 adjacent to the corresponding column of first contact plugs 220, and may be disposed to be closer to the corresponding column of first contact plugs 220 than to another column of first contact plugs 220. In an example, as shown, in the second direction, the left initial hard mask pattern 240 corresponding to the left column of first contact plugs 220 may be disposed between the left column of first contact plugs 220 and the right column of first contact plugs 220, and may be disposed closer to the left column of first contact plugs 220 than to the right column of first contact plugs 220.

Since the initial selector pattern 234 is etched using the initial hard mask pattern 240, the initial selector pattern 234 may be located under the initial hard mask pattern 240, and may have a shape that overlaps the initial hard mask pattern 240 in a plan view. Accordingly, the shape and position of the initial selector pattern 234 may be substantially the same as the shape and position of the initial hard mask pattern 240, in a plan view. Thus, the initial selector pattern 234 may have a line shape extending in the first direction, and may be disposed at one side of a corresponding column of first contact plugs 220 in the second direction to be spaced apart from the corresponding column of first contact plugs 220 by a predetermined distance. Furthermore, in the second direction, the initial selector pattern 234 may be disposed between the corresponding column of first contact plugs 220 and another column of first contact plugs 220 adjacent to the corresponding column of first contact plugs 220, and may be disposed to be closer to the corresponding column of first contact plugs 220 than to another column of first contact plugs 220. The initial selector pattern 234 may have both sidewalls aligned with both sidewalls of the initial hard mask pattern 240 in the second direction. In the second direction, both sidewalls of the stacked structure of the initial hard mask pattern 240 and the initial selector pattern 234 will hereinafter be referred to as a first sidewall S1 and a second sidewall S2. The first sidewall S1 and the second sidewall S2 may correspond to the left sidewall and the right sidewall, respectively, and may face each other.

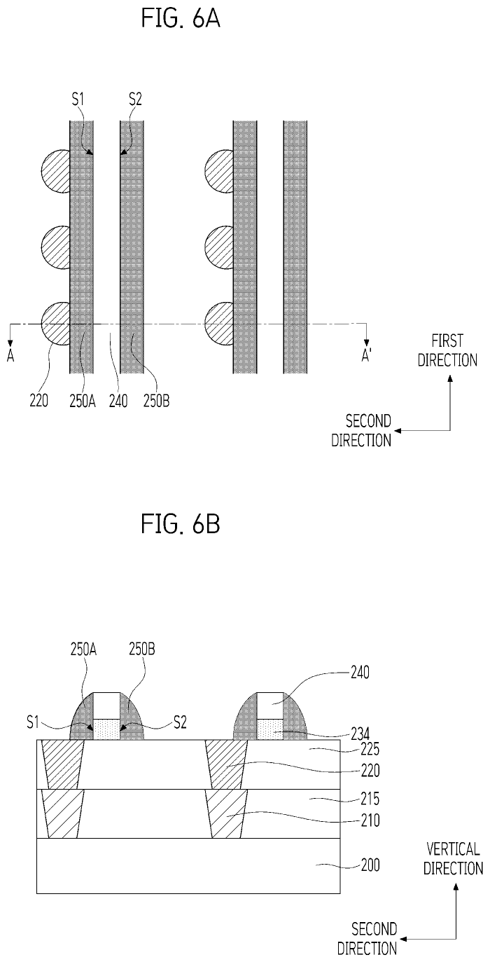

Referring to FIGS. 6A and 6B, an initial first electrode layer 250A and an initial second electrode layer 250B may be formed over the first sidewall S1 and the second sidewall S2 of the stacked structure of the initial hard mask pattern 240 and the initial selector pattern 234, respectively. The initial first electrode layer 250A and the initial second electrode layer 250B may be substantially symmetrical to each other with respect to the stacked structure of the initial hard mask pattern 240 and the initial selector pattern 234, which is interposed therebetween.

Each of the initial first electrode layer 250A and the initial second electrode layer 250B may include at least one of various conductive materials, for example, a metal such as platinum (Pt), tungsten (W), aluminum (Al), copper (Cu), tantalum (Ta), or titanium (Ti), a metal nitride such as titanium nitride (TiN) or tantalum nitride (TaN), or a combination thereof. The initial first electrode layer 250A and the initial second electrode layer 250B may be formed by depositing a conductive material conformally along the lower profile over the process result of FIGS. 5A and 5B, and performing blanket etching. The blanket etching may be performed to expose the upper surface of the initial hard mask pattern 240 and the upper surface of the second interlayer insulating layer 225. As a result of the blanket etching process, each of the initial first electrode layer 250A and the initial second electrode layer 250B in the second direction may have a shape whose width increases from top to bottom. Such shape of the initial first electrode layer 250A and the initial second electrode layer 250B, which increases from top to bottom, may be referred to as a sidewall spacer shape. Accordingly, the width of the lowermost surface of each of the initial first electrode layer 250A and the initial second electrode layer 250B may be maximum. Here, the lowermost surface of the initial first electrode layer 250A may overlap and contact the upper surfaces of the first contact plugs 220 belonging to the corresponding column of first contact plugs 220, thereby being connected to the corresponding column of first contact plugs 220. In an example, as shown, the first initial electrode layer 250A disposed over a left first sidewall S1 may overlap and contact the upper surfaces of the first contact plugs 220 belonging to the left column of first contact plugs 220 to be connected thereto. On the other hand, the lowermost surface of the initial second electrode layer 250B may not only be spaced apart from the corresponding column of first contact plugs 220, but also may be spaced apart from another column of first contact plugs 220. In an example, as shown, the lowermost surface of the initial second electrode layer 250B disposed over a left second sidewall S2 may be spaced apart from the left column of first contact plugs 220 and the right column of first contact plugs 220.

In the present embodiment, the lowermost surface of the initial first electrode layer 250A may partially overlap and contact the upper surfaces of the first contact plugs 220 belonging to the corresponding column of first contact plugs 220. Thus, the upper surfaces of the first contact plugs 220 belonging to the corresponding column of first contact plugs 220 may be partially exposed by the initial first electrode layer 250A. However, the present disclosure is not limited thereto. In another embodiment, the width of the lowermost surface of the initial first electrode layer 250A may be increased, and may overlap and contact all of the upper surfaces of the first contact plugs 220 belonging to the corresponding column of first contact plugs 220. Even in this case, the initial second electrode layer 250B may be separated from another column of first contact plugs 220.

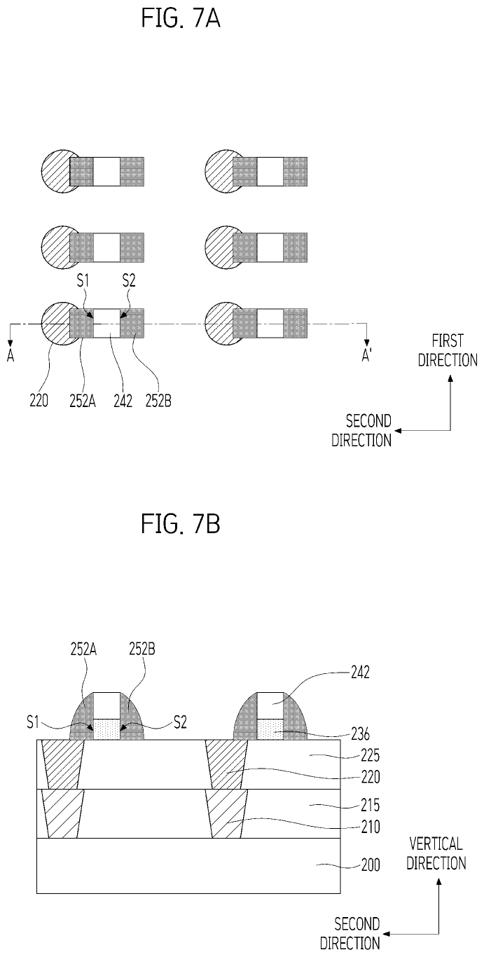

Referring to FIGS. 7A and 7B, the stacked structure of the initial selector pattern 234 and the initial hard mask pattern 240, and the initial first and second electrode layers 250A and 250B located over both sidewalls of the stacked structure and extending in the first direction may be etched so that the stacked structure and the initial first and second electrode layers 250A and 250B are separated into a plurality of parts in the second direction. As a result, a stacked structure of a selector pattern 236 and a hard mask pattern 242, and first and second electrode layers 252A and 252B may be formed.

This etching process may be performed using a line-shaped mask pattern (not shown) extending in the second direction. In addition, this etching process may be performed in a state in which the mask pattern is formed over an insulating material (not shown) that is formed to fill the space between the initial first and second electrode layers 250A and 250B.

The stacked structure of the selector pattern 236 and the hard mask pattern 242 may have a rectangular shape or a square shape in a plan view. The first and second electrode layers 252A and 252B may be formed over both sidewalls, that is, the first sidewall S1 and the second sidewall S2 of the stacked structure of the selector pattern 236 and the hard mask pattern 242 in the second direction. Each of the first and second electrode layers 252A and 252B may have a rectangular shape or a square shape in a plan view. The cross-sectional shapes of the selector pattern 236, the hard mask pattern 242, and the first and second electrode layers 252A and 252B may be substantially the same as those of FIG. 6B.

A structure including one stacked structure of the selector pattern 236 and the hard mask pattern 242, and first and second electrode layers 252A and 252B respectively formed over the first and second sidewalls S1 and S2 of one stacked structure, will be referred to as a first structure. A plurality of first structures may correspond to the plurality of first contact plugs 220, respectively, and may be arranged in a matrix form along the first and second directions.

Here, the stacked structure of the selector pattern 236 and the hard mask pattern 242 may be arranged at one side of a corresponding first contact plug 220 in the second direction to be spaced apart from the corresponding first contact plug 220 by a predetermined distance. Furthermore, in the second direction, the stacked structure of the selector pattern 236 and the hard mask pattern 242 may be disposed between the corresponding first contact plug 220 and another first contact plug 220 adjacent thereto to be closer to the corresponding first contact plug 220. The lowermost surface of the first electrode layer 252A may be connected to the corresponding first contact plug 220 by overlapping and contacting at least a portion of the upper surface of the corresponding first contact plug 220. The lowermost surface of the second electrode layer 252B may be spaced apart from the corresponding first contact plug 220 and another first contact plug 220 between them. In the present embodiment, the first electrode layer 252A partially overlaps and contacts the upper surface of the corresponding first contact plug 220, but the present disclosure is not limited thereto. In another embodiment, the first electrode layer 252A may overlap and contact the entire upper surface of the corresponding first contact plug 220.

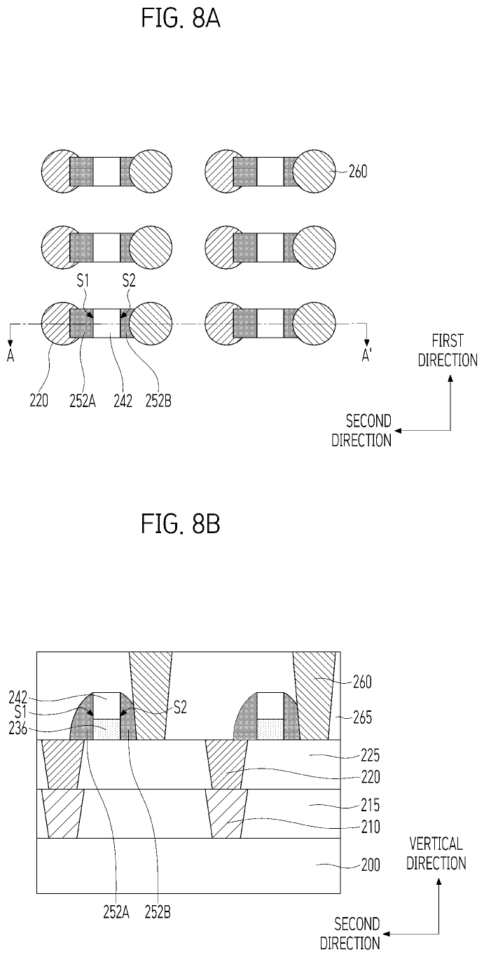

Referring to FIGS. 8A and 8B, a third interlayer insulating layer 265 may be formed to cover the process result of FIGS. 7A and 7B.

Subsequently, a second contact plug 260 may be formed to penetrate the third interlayer insulating layer 265 and overlap the second electrode layer 252B. Thus, the second contact plug 260 may be disposed in contact with the second electrode layer 252B.

The second contact plug 260 may have a pillar shape, and a plurality of second contact plugs 260 may be arranged in a matrix form along the first and second directions. The plurality of second contact plugs 260 may be respectively connected to the plurality of second electrode layers 252B. The second contact plug 260 may be formed by selectively etching the third interlayer insulating layer 265 to form a hole that provides a space in which the second contact plug 260 is to be formed, and filling the hole with a conductive material. As shown, a portion of the second electrode layer 252B may be lost during the etching process for forming the hole, and accordingly, the second electrode layer 252B may no longer have a symmetrical shape with the first electrode layer 252A. However, the present disclosure is not limited thereto, and the second electrode layer 252B may be substantially maintained during the etching process for forming the hole. In this case, the second electrode layer 252B may have a symmetrical shape with first electrode layer 252A. As long as the sidewall of the second contact plug 260 contacts the second electrode layer 252B and is electrically connected to the second electrode layer 252B, the shape of the second electrode layer 252B may be variously modified. In any case, the width of the lowermost surface of each of the first electrode layer 252A and the second electrode layer 252B may be maximum.

Referring to FIGS. 9A and 9B, a second conductive line 270 may be formed over the third interlayer insulating layer 265 and the second contact plug 260.

The second conductive line 270 may extend in the second direction, and a plurality of second conductive lines 270 may be arranged to be spaced apart from each other in the first direction. When the plurality of second contact plugs 270 arranged in the second direction is referred to as a row of second contact plugs 270, the second conductive line 270 may overlaps and be connected to the row of second contact plugs 270.

The semiconductor device of the present embodiment may be fabricated through the processes described above.

The semiconductor device of the present embodiment may include the substrate 200, the first conductive line 210 disposed over the substrate 200 and extending in the first direction, the first contact plug 220 disposed over the first conductive line 210 and connected to the first conductive line 210, the stacked structure of the selector pattern 236 and the hard mask pattern 242 disposed over the first contact plug 220 and disposed at one side of the first contact plug 220 in the second direction to be spaced apart from the first contact plug 220, the first electrode layer 252A formed over the first sidewall S1 of the stacked structure of the selector pattern 236 and the hard mask pattern 242 in the second direction and having the lowermost surface contacting at least a portion of the upper surface of the first contact plug 220, the second electrode layer 252B formed over the second sidewall S2 of the stacked structure of the selector pattern 236 and the hard mask pattern 242 in the second direction, the second contact plug 260 having the sidewall contacting the second electrode layer 252B at one side of the second electrode layer 252B, and the second conductive line 270 disposed over the second contact plug 260 to be connected to the second contact plug 260 and extending in the second direction.

When one of the first conductive line 210 and the second conductive line 270 functions as a word line, the other of the first conductive line 210 and the second conductive line 270 may function as a bit line. The first contact plug 220 may function to connect the first conductive line 210 and the first electrode layer 252A between them, and may form a contact with the first electrode layer 252A in the vertical direction. The second contact plug 220 may function to connect the second conductive line 270 and the second electrode layer 252B between them, and may form a contact with the second electrode layer 252B in the horizontal direction.

The first electrode layer 252A and the second electrode layer 252B may be respectively formed over the first sidewall S1 and the second sidewall S2 of the selector pattern 236, and may serve as two electrodes for driving the selector pattern 236. The first electrode layer 252A may correspond to any one of the first and second electrode layers 110 and 130 of FIG. 1 described above, and the second electrode layer 252B may correspond to the other one of the first and second electrode layers 110 and 130 of FIG. 1 described above. In this case, since the current flow through the selector pattern 236 is formed between the first electrode layer 252A and the second electrode layer 252B, the current flow may occur in a direction substantially parallel to the horizontal direction. For example, when a voltage higher than the threshold voltage is applied to turn on the selector pattern 236 through the first and second conductive lines 210 and 270, a current flow as indicated by an arrow may occur, and this current flow may occur in the horizontal direction within the selector pattern 236 (see dotted line within the selector pattern 236). As described above, since the implantation of the dopants for forming the selector pattern 236 is performed in the vertical direction, the dopant profile in the selector pattern 236 exhibits a Gaussian distribution in the vertical direction, while being substantially uniform in the horizontal direction. As a result, according to the present embodiment, since the dopant concentration is substantially uniform in the direction of the current flow through the selector pattern 236, the switching characteristic of the selector pattern 236 may be improved.

Since the components of the semiconductor device of the present embodiment have already been described in detail in the fabricating method, further detailed description of the components will be omitted here.

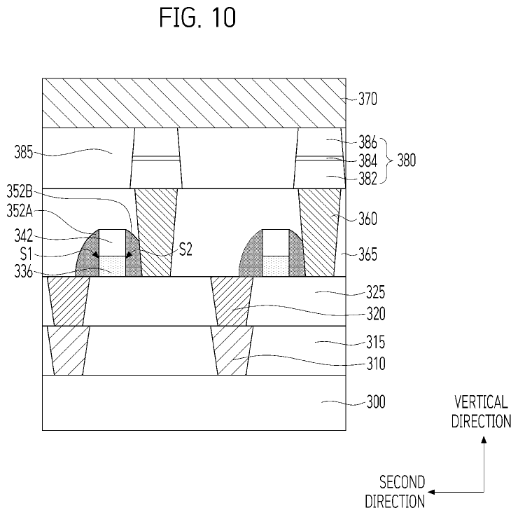

The selector pattern of the above-described embodiment may be electrically connected to a memory pattern that functions to store data, and may function to control access to the memory pattern. A semiconductor device including a memory pattern connected to a selector pattern, and a method for fabricating the same will be exemplarily described with reference to FIGS. 10 to 13 below.

FIG. 10 is a cross-sectional view illustrating a semiconductor device according to another embodiment of the present disclosure, and a method for fabricating the same. The description will focus on differences from the above-described embodiment.

Referring to FIG. 10, a semiconductor device of the present embodiment may include a substrate 300, a first conductive line 310 disposed over the substrate 300 and extending in a first direction, a first contact plug 320 disposed over the first conductive line 310 and connected to the first conductive line 310, a stacked structure of a selector pattern 336 and a hard mask pattern 342 disposed over the first contact plug 320 and disposed at one side of the first contact plug 320 in a second direction to be spaced apart from the first contact plug 320, a first electrode layer 352A formed over a first sidewall S1 of the stacked structure of the selector pattern 336 and the hard mask pattern 342 in the second direction and having a lowermost surface contacting at least a portion of the upper surface of the first contact plug 320, a second electrode layer 352B formed over a second sidewall S2 of the stacked structure of the selector pattern 336 and the hard mask pattern 342 in the second direction, a second contact plug 360 having a sidewall contacting the second electrode layer 352B at one side of the second electrode layer 352B, a memory pattern 380 disposed over the second contact plug 360 and connected to the second contact plug 360, and a second conductive line 370 disposed over the memory pattern 380 to be connected to the memory pattern 380 and extending in the second direction. Reference numerals 315, 325, 365, and 385 that are not described may correspond to interlayer insulating layers.

In the present embodiment, the memory pattern 380 may be disposed between the second contact plug 360 and the second conductive line 370, and thus, the memory pattern 380 may be located above the selector pattern 336. The memory pattern 380 may have a pillar shape, and a plurality of memory patterns 380 may overlap and be connected to the plurality of second contact plugs 360, respectively.

The memory pattern 380 may store data in various ways, and may have various materials and structures. In an example, memory pattern 380 may include a capacitor. Alternatively, in an example, the memory pattern 380 may include a variable resistance pattern that stores different data by switching between different resistance states. The variable resistance pattern may include at least one of various materials used in RRAM, PRAM, FRAM, MRAM, etc., for example, a metal oxide such as a transition metal oxide or a perovskite-based material, a phase change material such as a chalcogenide-based material, a ferroelectric material, or a ferromagnetic material, and may have a single-layer structure or a multi-layer structure.

In the present embodiment, the memory pattern 380 may include a magnetic tunnel junction structure including a pinned layer 382, a tunnel barrier layer 384, and a free layer 386. The pinned layer 382 may be a layer that has a fixed magnetization direction to be contrasted with the magnetization direction of the free layer 386, and may also be called a reference layer. The free layer 386 may be a layer that stores different data by having a changeable magnetization direction, and may also be called a storage layer. The tunnel barrier layer 384 may physically separate the pinned layer 382 and the free layer 386, and may enable tunneling of electrons between them. Each of the pinned layer 382 and the free layer 386 may have a single-layer structure or a multi-layer structure including a ferromagnetic material. In an example, each of the pinned layer 382 and the free layer 386 may include an alloy containing Fe, Ni, or Co as a main component, such as Fe—Pt alloy, Fe—Pd alloy, Co—Pd alloy, Co—Pt alloy, Fe—Ni—Pt alloy, Co—Fe—Pt alloy, Co—Ni—Pt alloy, or Co—Fe—B alloy, or, a stacked structure of Co/Pt or Co/Pd. The tunnel barrier layer 384 may have a single-layer structure or a multi-layer structure including an insulating material. In an example, the tunnel barrier layer 384 may include an insulating oxide such as MgO, CaO, SrO, TiO, VO, or NbO. In this magnetic tunnel structure, the magnetization direction of the free layer 386 may vary depending on the applied voltage or current. When the magnetization direction of the free layer 386 is parallel to the magnetization direction of the pinned layer 382, the magnetic tunnel junction structure may have a low resistance state and, for example, may store data ‘1’. On the other hand, when the magnetization direction of the free layer 386 is anti-parallel to the magnetization direction of the pinned layer 382, the magnetic tunnel junction structure may have a high resistance state and, for example, may store data ‘0’. As long as the magnetic tunnel junction structure includes the pinned layer 382, the free layer 386, and the tunnel barrier layer 384 therebetween, the layer structure of the magnetic tunnel junction structure may be modified in various ways. In an example, the positions of the pinned layer 382 and the free layer 386 may be reversed with each other. Alternatively, for example, although not shown, one or more layers to improve the characteristics of the magnetic tunnel junction structure may be further included to the magnetic tunnel junction structure.

This memory pattern 380 may be formed by depositing material layers for forming the memory pattern 380, for example, the pinned layer 382, the tunnel barrier layer 384, and the free layer 386, over the second contact plug 360 and the third interlayer insulating layer 365, and selectively etching the material layers. Accordingly, the memory pattern 380 may have a width that increases from top to bottom.

When the selector pattern 336 is turned on by the voltage applied through the first conductive line 310 and the second conductive line 370, access to the memory pattern 380 may become possible, and thus, the memory pattern 380 can perform various operations, for example, a write operation of storing data in the memory pattern 380, a read operation of reading data stored in the memory pattern 380, or others. On the other hand, when the selector pattern 336 is turned off, access to the memory pattern 380 may be blocked.

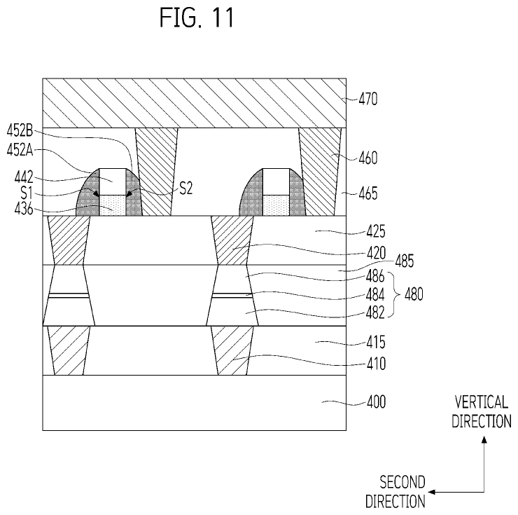

FIG. 11 is a cross-sectional view illustrating a semiconductor device according to another embodiment of the present disclosure, and a method for fabricating the same. The description will focus on differences from the above-described embodiment.

Referring to FIG. 11, a semiconductor device of the present embodiment may include a substrate 400, a first conductive line 410 disposed over the substrate 400 and extending in a first direction, a memory pattern 480 disposed over the first conductive line 410 and connected to the first conductive line 410, a first contact plug 420 disposed over the memory pattern 480 and connected to the memory pattern 480, a stacked structure of a selector pattern 436 and a hard mask pattern 442 disposed over the first contact plug 420 and disposed at one side of the first contact plug 420 in a second direction to be spaced apart from the first contact plug 420, a first electrode layer 452A formed over a first sidewall S1 of the stacked structure of the selector pattern 436 and the hard mask pattern 442 in the second direction and having a lowermost surface contacting at least a portion of the upper surface of the first contact plug 420, a second electrode layer 452B formed over a second sidewall S2 of the stacked structure of the selector pattern 436 and the hard mask pattern 442 in the second direction, a second contact plug 460 having a sidewall contacting the second electrode layer 452B at one side of the second electrode layer 452B, and a second conductive line 470 disposed over the second contact plug 460 to be connected to the second contact plug 460 and extending in the second direction. Reference numerals 415, 425, 465, and 485 that are not described may correspond to interlayer insulating layers.

In the present embodiment, the memory pattern 480 may be formed between the first contact plug 420 and the first conductive line 410, and thus, the memory pattern 380 may be located below the selector pattern 436. The memory pattern 480 may have a pillar shape, and a plurality of memory patterns 480 may overlap and be connected to the plurality of first contact plugs 420, respectively.

The memory pattern 480 may store data in various ways, and may have various materials and structures. In an example, the memory pattern 480 may include a magnetic tunnel junction structure including a pinned layer 482, a tunnel barrier layer 484, and a free layer 486. However, the present disclosure is not limited thereto, and the memory pattern 480 may include various layer structures and materials as long as it stores data.

This memory pattern 480 may be formed by depositing material layers for forming the memory pattern 480, for example, the pinned layer 482, the tunnel barrier layer 484, and the free layer 486, over the first conductive line 410 and the first interlayer insulating layer 415, and selectively etching the material layers. Accordingly, the memory pattern 480 may have a width that increases from top to bottom.

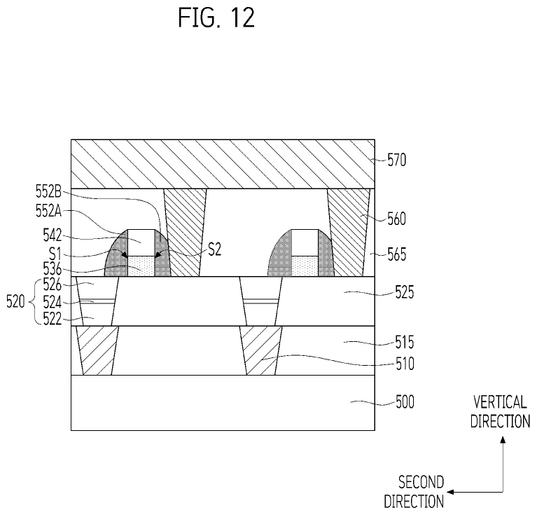

FIG. 12 is a cross-sectional view illustrating a semiconductor device according to another embodiment of the present disclosure, and a method for fabricating the same. The description will focus on differences from the above-described embodiment.

Referring to FIG. 12, a semiconductor device of the present embodiment may include a substrate 500, a first conductive line 510 disposed over the substrate 500 and extending in a first direction, a memory pattern 520 disposed over the first conductive line 510 and connected to the first conductive line 510, a stacked structure of a selector pattern 536 and a hard mask pattern 542 disposed over the memory pattern 520 and disposed at one side of the memory pattern 520 in a second direction to be spaced apart from the memory pattern 520, a first electrode layer 552A formed over a first sidewall S1 of the stacked structure of the selector pattern 536 and the hard mask pattern 542 in the second direction and having a lowermost surface contacting at least a portion of the upper surface of the memory pattern 520, a second electrode layer 552B formed over a second sidewall S2 of the stacked structure of the selector pattern 536 and the hard mask pattern 542 in the second direction, a second contact plug 560 having a sidewall contacting the second electrode layer 552B at one side of the second electrode layer 552B, and a second conductive line 570 disposed over the second contact plug 560 to be connected to the second contact plug 560 and extending in the second direction. Reference numerals 515, 525, and 565 that are not described may correspond to interlayer insulating layers.

In the present embodiment, the first contact plug of the above-described embodiments may be omitted, and the first contact plug may be replaced with the memory pattern 520. That is, the memory pattern 520 may be disposed between the first conductive line 510 and the first electrode layer 552A, and may have an upper surface in direct contact with the lower surface of the first electrode layer 552A. The lower surface of the first electrode layer 552A may contact at least a portion of the upper surface of the memory pattern 520. The memory pattern 520 may have a pillar shape, and a plurality of memory patterns 520 may overlap and be connected to the plurality of first electrode layers 552A, respectively.

The memory pattern 520 may store data in various ways, and may have various materials and structures. In an example, the memory pattern 520 may include a magnetic tunnel junction structure including a pinned layer 522, a tunnel barrier layer 524, and a free layer 526. However, the present disclosure is not limited thereto, and the memory pattern 520 may include various layer structures and materials as long as it stores data.

The memory pattern 520 may be formed by depositing the interlayer insulating layer 525 over the first conductive line 510, selectively etching the interlayer insulating layer 525 to form a hole exposing the first conductive line 510, and filling material layers for forming the memory pattern 520 within the hole. In this case, the memory pattern 520 may have a width that decreases from top to bottom. When the memory pattern 520 includes a multi-layer structure, for example, the stacked structure of the pinned layer 522, the tunnel barrier layer 524, and the free layer 526 as shown, the material layers for forming the memory pattern 520 may be filled within the hole in the following manner. First, a magnetic layer for forming the pinned layer 522 may be deposited along the sidewall and the lower surface of the hole to a thickness that does not completely fill the hole, and an etching process such as etch-back may be performed so that a portion of the magnetic layer disposed on the sidewall of the hole is removed, thereby forming the pinned layer 522. Subsequently, an insulating layer for forming the tunnel barrier layer 524 may be deposited over the pinned layer 522 along the sidewall and the lower surface of the remaining space of the hole where the pinned layer 522 is formed to a thickness that does not completely fill the remaining space of the hole, and an etching process such as etch-back may be performed so that a portion of the insulating layer disposed on the sidewall of the hole is removed, thereby forming the tunnel barrier layer 524. Subsequently, a magnetic layer for forming the free layer 526 may be deposited over the tunnel barrier layer 524 to a thickness that fills the hole, and a planarization process may be performed to expose the upper surface of the interlayer insulating layer 525, thereby forming the free layer 526. Deposition of the magnetic layer or the insulating layer may be performed, for example, by an ALD (Atomic Layer Deposition) method. As a result, the memory pattern 520 as shown may be formed. However, the present disclosure is not limited thereto, and it may be possible to fill the memory pattern 520 having a multi-layer structure in the hole in various ways.

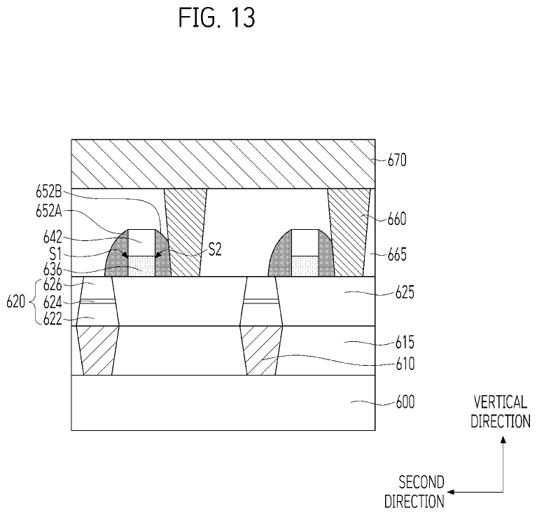

FIG. 13 a cross-sectional view illustrating a semiconductor device according to another embodiment of the present disclosure, and a method for fabricating the same. The description will focus on differences from the above-described embodiment.

Referring to FIG. 13, a semiconductor device of the present embodiment may include a substrate 600, a first conductive line 610 disposed over the substrate 600 and extending in a first direction, a memory pattern 620 disposed over the first conductive line 610 and connected to the first conductive line 610, a stacked structure of a selector pattern 636 and a hard mask pattern 642 disposed over the memory pattern 620 and disposed at one side of the memory pattern 620 in a second direction to be spaced apart from the memory pattern 620, a first electrode layer 652A formed over a first sidewall S1 of the stacked structure of the selector pattern 636 and the hard mask pattern 642 in the second direction and having a lowermost surface contacting at least a portion of the upper surface of the memory pattern 620, a second electrode layer 652B formed over a second sidewall S2 of the stacked structure of the selector pattern 636 and the hard mask pattern 642 in the second direction, a second contact plug 660 having a sidewall contacting the second electrode layer 652B at one side of the second electrode layer 652B, and a second conductive line 670 disposed over the second contact plug 660 to be connected to the second contact plug 660 and extending in the second direction. Reference numerals 615, 625, and 665 that are not described may correspond to interlayer insulating layers.

In the present embodiment, the first contact plug of the above-described embodiments may be omitted, and the first contact plug may be replaced with the memory pattern 620. That is, the memory pattern 620 may be disposed between the first conductive line 610 and the first electrode layer 652A, and may have an upper surface in direct contact with the lower surface of the first electrode layer 652A. The lower surface of the first electrode layer 652A may contact at least a portion of the upper surface of the memory pattern 620. The memory pattern 620 may have a pillar shape, and a plurality of memory patterns 620 may overlap and be connected to the plurality of first electrode layers 652A, respectively.

The memory pattern 620 may store data in various ways, and may have various materials and structures. In an example, the memory pattern 620 may include a magnetic tunnel junction structure including a pinned layer 622, a tunnel barrier layer 624, and a free layer 626. However, the present disclosure is not limited thereto, and the memory pattern 620 may include various layer structures and materials as long as it stores data.

The memory pattern 620 may be formed by depositing material layers for forming the memory pattern 620, such as the pinned layer 622, the tunnel barrier layer 624, and the free layer 626, and selectively etching the material layers. In this case, the memory pattern 620 may have a width that increases from top to bottom. Deposition of the material layers may be performed, for example, by a PVD (Physical Vapor Deposition) method. As a result, a memory pattern 620 as shown may be formed.

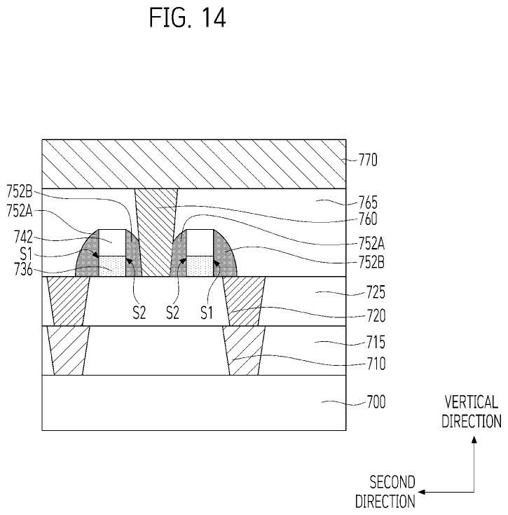

In the above embodiments, the plurality of second contact plugs are in contact with the plurality of second electrode layers, respectively, and thus, the plurality of second contact plugs are electrically connected to the plurality of selector patterns, respectively, but the present disclosure is not limited thereto. In another embodiment, two second electrode layers may be disposed at both sides of one second contact plug in the second direction, and one second contact plug may commonly contact the two second electrode layers. Accordingly, in the second direction, two selector patterns may share one second contact plug, and may be commonly connected to one second contact plug. This will be exemplarily described with reference to FIG. 14.

FIG. 14 is a cross-sectional view illustrating a semiconductor device according to another embodiment of the present disclosure.

Referring to FIG. 14, a semiconductor device of the present embodiment may include a substrate 700, a first conductive line 710 disposed over the substrate 700 and extending in a first direction, a first contact plug 720 disposed over the first conductive line 710 and connected to the first conductive line 710, a stacked structure of a selector pattern 736 and a hard mask pattern 742 disposed over the first contact plug 720 and disposed at one side of the first contact plug 720 in a second direction to be spaced apart from the first contact plug 720, a first electrode layer 752A formed over a first sidewall S1 of the stacked structure of the selector pattern 736 and the hard mask pattern 742 in the second direction and having a lowermost surface contacting at least a portion of the upper surface of the first contact plug 720, a second electrode layer 752B formed over a second sidewall S2 of the stacked structure of the selector pattern 736 and the hard mask pattern 742 in the second direction, a second contact plug 760 having a sidewall contacting the second electrode layer 752B at one side of the second electrode layer 752B, and a second conductive line 770 disposed over the second contact plug 760 to be connected to the second contact plug 760 and extending in the second direction. Reference numerals 715, 725, and 765 that are not described may correspond to interlayer insulating layers.

Here, two first contact plugs 720 arranged in the second direction will be referred to as left and right first contact plugs 720, and two stacked structures of the selector pattern 736 and the hard mask pattern 742 respectively corresponding to the left and right first contact plugs 720 will be referred to as left and right stacked structures. The left stacked structure may be placed at a right side of the left first contact plug 720, while the right stacked structure may be placed at a left side of the right first contact plug 720. Accordingly, in the left stacked structure, the first sidewall S1 and the second sidewall S2 may be located at a left side and a right side, respectively, while in the right stacked structure, the first sidewall S1 and the second sidewall S2 may be located at a right side and a left side, respectively. This may be because the first sidewall S1 is closer to the corresponding first contact plug 720 than the second sidewall S2. In addition, the left first electrode layer 752A may be located over the first sidewall S1 to be located at the left side of the left stacked structure, while the right first electrode layer 752A may be located over the first sidewall S1 to be located at the right side of the right stacked structure. The left second electrode layer 752B and the right second electrode layer 752B may be disposed to face each other between the left and right stacked structures. The second contact plug 760 may have a sidewall that is in common contact with the left second electrode layer 752B and the right second electrode layer 752B between them.

According to the present embodiment, the area of the semiconductor device may be further reduced.

According to the above embodiments of the present disclosure, it may be possible to improve the characteristic of a selector in a semiconductor device.

While the disclosed technology has been illustrated and described with respect to specific embodiment, it should be understood that various enhancements and modifications of the disclosed embodiments and other embodiments may be made based on what is described and illustrated in this patent document.

What is claimed is:

1. A semiconductor device, comprising:
a selector pattern including an insulating material having dopants implanted to the insulating material along an implantation direction and having a first sidewall and a second sidewall facing the first sidewall, the selector pattern configured to exhibit different electrical conducting characteristics in response to an applied voltage with respect to a threshold voltage; and
a first electrode layer and a second electrode layer respectively formed over the first sidewall and the second sidewall of the selector pattern,
wherein the implantation direction of the dopants is different from a direction of a current flowing through the selector pattern between the first electrode layer and the second electrode layer when the selector pattern is turned on.

2. The semiconductor device according to claim 1, wherein each of the first electrode layer and the second electrode layer has a shape where a width of a lowermost surface is maximum.

3. The semiconductor device according to claim 1, further comprising:
a first contact plug having an upper surface in contact with a lower surface of the first electrode layer and disposed under the first electrode layer; and
a second contact plug having a sidewall in contact with the second electrode layer at one side of the second electrode layer.

4. The semiconductor device according to claim 3, further comprising:
a first conductive line connected to the first contact plug and disposed under the first contact plug; and
a second conductive line connected to the second contact plug and disposed over the second contact plug.

5. The semiconductor device according to claim 4, further comprising:
a memory pattern interposed between the first contact plug and the first conductive line.

6. The semiconductor device according to claim 4, further comprising:
a memory pattern interposed between the second contact plug and the second conductive line.

7. The semiconductor device according to claim 1, further comprising:
a memory pattern having an upper surface in contact with a lower surface of the first electrode layer and disposed under the first electrode layer; and
a second contact plug having a sidewall in contact with the second electrode layer at one side of the second electrode layer.

8. The semiconductor device according to claim 7, further comprising:
a first conductive line connected to the memory pattern and disposed under the memory pattern; and
a second conductive line connected to the second contact plug and disposed over the second contact plug.

9. The semiconductor device according to claim 7, wherein a width of the memory pattern decreases in a downward direction.

10. A semiconductor device comprising:
a first conductive line and a second conductive line that are spaced apart from each other in a vertical direction;
a selector pattern interposed between the first conductive line and the second conductive line in the vertical direction and including a first sidewall and a second sidewall facing the first sidewall in a horizontal direction, the selector pattern configured to exhibit different electrical conducting characteristics in response to an applied voltage with respect to a threshold voltage;
a first electrode layer and a second electrode layer respectively formed over the first sidewall and the second sidewall of the selector pattern;
a first contact plug having an upper surface in contact with a lower surface of the first electrode layer, the first contact plug electrically connected to the first conductive line and disposed over the first conductive line; and
a second contact plug disposed at one side of the second electrode layer in the horizontal direction and having a sidewall in contact with the second electrode layer, the second contact plug electrically connected to the second conductive line and disposed under the second conductive line.

11. The semiconductor device according to claim 10, wherein the selector pattern includes an insulating material having dopants implanted to the insulating material along an implantation direction that is different from a direction of a current flowing through the selector pattern between the first electrode layer and the second electrode layer in response to the selector pattern being turned on.

12. The semiconductor device according to claim 10, wherein the first electrode layer and the second electrode layer have widths that increase in a downward direction.

13. The semiconductor device according to claim 10, wherein the selector pattern includes a first selector pattern and a second selector pattern that are arranged in the horizontal direction,
the first electrode layer includes a first portion and a second portion that are respectively formed over first sidewalls of the first selector pattern and the second selector pattern,
the second electrode layer includes a first portion and a second portion that are respectively formed over second sidewalls of the first selector pattern and the second selector pattern,
the first contact plug includes a first portion contacting the first portion of the first electrode layer and a second portion contacting the second portion of the first electrode layer, and
the second contact plug includes a first portion contacting the first portion of the second electrode layer and a second portion contacting the second portion of the second electrode layer.

14. The semiconductor device according to claim 13, wherein the first portion of the second electrode layer and the second portion of the first electrode layer are disposed to face each other.

15. The semiconductor device according to claim 10, wherein the selector pattern includes a first selector pattern and a second selector pattern that are arranged in the horizontal direction,
the first electrode layer includes a first portion and a second portion that are respectively formed over first sidewalls of the first selector pattern and the second selector pattern,
the second electrode layer includes a first portion and a second portion that are respectively formed over second sidewalls of the first selector pattern and the second selector pattern,
the first contact plug includes a first portion contacting the first portion of the first electrode layer and a second portion contacting the second portion of the first electrode layer, and
the first portion and the second portion of the second electrode layer face each other and are in common contact with the second contact plug.

16. The semiconductor device according to claim 10, further comprising:
a memory pattern interposed between the first contact plug and the first conductive line.

17. The semiconductor device according to claim 10, further comprising:
a memory pattern interposed between the second contact plug and the second conductive line.

18. A semiconductor device, comprising:
a first conductive line and a second conductive line that are spaced apart from each other in a vertical direction;
a selector pattern interposed between the first conductive line and the second conductive line in the vertical direction and including a first sidewall and a second sidewall that face each other in a horizontal direction;
a first electrode layer and a second electrode layer that are respectively formed over the first sidewall and the second sidewall of the selector pattern;
a memory pattern having an upper surface in contact with a lower surface of the first electrode layer, the memory pattern electrically connected to the first conductive line and disposed over the first conductive line; and
a contact plug disposed at one side of the second electrode layer in the horizontal direction and having a sidewall in contact with the second electrode layer, the contact plug electrically connected to the second conductive line and disposed under the second conductive line.

19. The semiconductor device according to claim 18, wherein the selector pattern includes an insulating material having dopants implanted to the insulating material along an implantation direction that is different from a direction of a current flowing through the selector pattern between the first electrode layer and the second electrode layer in response to the selector pattern being turned on.

20. The semiconductor device according to claim 18, wherein the first electrode layer and the second electrode layer have widths that increase in a downward direction.

21. The semiconductor device according to claim 18, wherein the selector pattern includes a first selector pattern and a second selector pattern that are arranged in the horizontal direction,
the first electrode layer includes a first portion and a second portion that are respectively formed over first sidewalls of the first selector pattern and the second selector pattern,
the second electrode layer includes a first portion and a second portion that are respectively formed over second sidewalls of the first selector pattern and the second selector pattern, and
the contact plug includes a first portion contacting the first portion of the second electrode layer and a second portion contacting the second portion of the second electrode layer.

22. The semiconductor device according to claim 21, wherein the first portion of the second electrode layer and the second portion of the first electrode layer face each other.

23. The semiconductor device according to claim 18, wherein the selector pattern includes a first selector pattern and a second selector pattern that are arranged in the horizontal direction,
the first electrode layer includes a first portion and a second portion that are respectively formed over first sidewalls of the first selector pattern and the second selector pattern,
the second electrode layer includes a first portion and a second portion that are respectively formed over second sidewalls of the first selector pattern and the second selector pattern, and
the first portion and the second portion of the second electrode layer face each other and are in common contact with the contact plug.
